(19) United States
(12) Patent Application Publication
(10) Pub. No.: US 2003/0104292 A1
(43) Pub. Date: Jun. 5, 2003

(54) Semiconductor device and fabrication method therefor

(75) Inventor: Yoshikatu Tomimatu, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/142,057

(22) Filed: May 10, 2002

(30) Foreign Application Priority Data
Dec. 3, 2001 (JP) 2001-368908 (P)

(51) Int. Cl. G03C 5/00; H01L 21/66; G01R 31/26

(52) U.S. Cl. 430/30; 438/16; 438/14; 430/296

(57) ABSTRACT

Preparations are performed in advance of obtaining data showing a relationship between a size and an exposure dose and data showing a relationship between a size and a focal position when three patterns for measuring changes in exposure conditions are formed. Then, the three patterns are actually formed on a semiconductor substrate and sizes of the patterns are measured. By estimating a change amount of the exposure dose, a change amount of the focal position and a direction of change in focal point between a data preparation step and a pattern formation step in an actual exposure process, an exposure dose and a focal position in an exposure apparatus for next lot are properly adjusted. As a result, obtained are a fabrication method for a semiconductor device, capable of controlling exposure conditions in an exposure process more strictly and a semiconductor device fabricated using the method.

### BACKGROUND OF THE INVENTION

1. Field of the Invention

The present invention relates to a fabrication method for a semiconductor device, capable of controlling exposure conditions and to a semiconductor device fabricated using the method.

2. Description of the Background Art

In recent years, a depth of focus (D. O. F) of a pattern formed on a semiconductor substrate has been increasingly shallower in company with miniaturization of a semiconductor device in a fabrication process thereof. Each of semiconductor device makers has been active in introducing a planarization technique such as chemical mechanical polishing (CMP) to cope with such a trend of depth of focus being shallower.

In a fabrication process of a semiconductor device in a factory, however, situations frequently arise where good semiconductor devices cannot be obtained under margins estimated at a designing stage. Major causes for such unfavorable situations are considered to be fluctuations in parameters associated the process. For example, to show causes in photolithography in details, there are various kinds of fluctuations in various ways such as fluctuations in light wavelength of an optical source, in output of an exposure dose of integrating monitor, in sensitivity of a photoresist, in exhaust in resist coating operation or developing operation and in other process parameters. Furthermore, human error should also be a factor.

As a measure to reduce the above fluctuations, feed-back has been adopted in a field of resistration accuracy measurement but not in a field exposure accuracy measurement. In FIG. 9, by way of comparison, the current states of the field of resistration accuracy measurement and the field of exposure accuracy measurement are shown with respect to measures for reducing the fluctuations.

In the field of resistration accuracy measurement, as a measure to reduce the fluctuations, as shown in A of FIG. 9, an offset, a scaling, a rotation, a shot magnification and shot rotation, in exposure operation for each lot, are inputted to an exposure apparatus as correction values A for correcting exposure conditions. In this situation, deviations in resistration should be zero. Actually, however, since the deviations are not reduced to zero, an resistration accuracy measurement follows the input of the correction values A. Correction values B are further obtained applying the method of least squares to data of resistration accuracies obtained by the inspection. Thus obtained correction values B and the correction values A adopted in exposure operation are used to derive a correction values C for the next lot.

In the field of exposure accuracy measurement, as shown in B of FIG. 9, an exposure dose and a focal position are set as correction values A similar to the case of a field of registration accuracy measurement and by inputting the correction values A, a pattern of a predetermined size is formed. In the field of exposure accuracy measurement as well, a size is practically not realized as a predetermined value to perfection; therefore a size inspection is performed. Data obtained by the inspection is analyzed to attain correction values B for an exposure dose and a focal position.

In the above feedback in the field of exposure accuracy measurement, however, there is no logic to be applied with the method of least squares combining an analytical result and a correction value, as shown with ? of shown in B of FIG. 9, due to the zero th degree expression as is in an offset or others in the field of resistration accuracy measurement; therefore, naturally, corresponding correction values for use in the next lot has not been able to obtain.

As a method for solving this problem, an invention is disclosed in Japanese Patent Laying-Open No. 11-307431(1999). The invention described in the publication of Japanese Patent Laying-Open No. 11-307431(1999) is characterized by that a difference between a deviation in focal point of a pattern with a fine pitch and a deviation in focal point of a pattern with a broad pitch are estimated, followed by feedback of the estimated difference to the next lot.

In the invention disclosed in Japanese Patent Laying-Open No. 11-307431(1999), however, no determination is available on whether a focal position is shifted to the plus side or the minus side. This is because a graph for use in estimation of a shift in focal position behaves like a quadratic function. For this reason, a risk exists that a focal position is changed in a direction opposite a direction along which to be actually changed. Therefore, according to the invention disclosed in Japanese Patent Laying-Open No. 11-307431(1999), no control on a direction of shift in focal position can be effected, unavoidably resulting in lack of strictness to its extreme in control on exposure conditions.

### SUMMARY OF THE INVENTION

It is an object of the present invention to provide a fabrication method for a semiconductor device, capable of controlling exposure conditions for a next exposure process more strictly by estimating a change amount of an exposure dose, a change amount of a focal position and a direction of change in focal position in an exposure apparatus used in an exposure process for the semiconductor device, and provide a semiconductor device fabricated using the method.

A fabrication method for a semiconductor device of the present invention is a fabrication method for a semiconductor device, capable of controlling exposure conditions by forming a prescribed pattern on a semiconductor substrate in an exposure process.

Furthermore, the above prescribed pattern meets the following conditions:

The prescribed pattern includes: a first pattern; a second pattern different in position in a height direction at which being formed from, but of the same shape and size as the first pattern; and a third pattern different in position in the height direction at which being formed and in size from, but of the same shape as the first pattern.

Moreover, sizes of the first pattern and the second pattern are set at such respective magnitudes that each receive no influence of a shift in focal position given in the exposure process and size of the third pattern is set at such a magnitude that receives an influence of a shift in focal position given in the exposure process.

In a fabrication process for a semiconductor device of the present invention, the following steps are performed:

First, a data preparation step is performed that is a step for preparations of obtaining data showing a relationship between a size and an exposure dose when the second pattern is formed and data showing a relationship between a size and a focal position when the third pattern is formed in the various exposure conditions including changes in exposure dose and focal position in the exposure process.

Then, a pattern formation step is performed of forming the first pattern, the second pattern and the third pattern in the exposure process in actual fabrication for a semiconductor device. Thereafter, an actual size measurement step is performed of measuring an actual size of each of the first pattern, the second pattern and the third pattern, formed in the pattern formation step.

In addition, an estimation step is performed of estimating a change amount of the exposure dose, a change amount of the focal position and a direction of change in the focal position between the data preparation step and the actual size measurement step using the data showing a relationship between a size and an exposure dose when the second pattern is formed and the data showing a relationship between a size and a focal position when the third pattern is formed, and the actual sizes of the first pattern, the second pattern and the third pattern.

Thereafter, an exposure-dose focal-position adjustment step is performed of properly adjusting an exposure dose and a focal position in a next exposure step using the change amount of the exposure dose, the change amount of the focal position and the direction of change in focal position estimated in the estimation step.

In the estimation step, the following steps are performed:

First an exposure-dose change-amount determination step is performed of determining the change amount of the exposure dose by comparing the actual size of the second pattern with the data showing a relationship between a size and an exposure dose when the second pattern is formed.

Then, a size difference calculation step is performed of calculating a value to be obtained by subtracting a difference between the actual size of the first pattern and the actual size of the second pattern from a difference between the actual size of the first pattern and the actual size of the third pattern as a difference in size between the first pattern and the third pattern caused only by a shift in the focal position.

Thereafter, a value is obtained of a size difference between the first pattern and the third pattern caused only by a shift in the focal point subtracted from the actual size of the third pattern. Then, a focal-position-change-amount focal-position-change-direction determination step is performed of estimating the change amount of the focal position and the direction of change in focal position by determining whether or not the value of the size difference is on the positive side or the negative side with respect to, or on a reference axis spaced the distance of a difference in position in the height direction from the best focus axis of the data showing a relationship between a size and a focal position when the third pattern is formed.

According to a fabrication method as described above, in the estimation step, estimation can be performed on a direction of change in focal position in addition to a change amount of an exposure dose and a change amount of a focal position in an exposure apparatus used in an exposure process for a semiconductor device, which therefore, enables strict control on exposure conditions for a next exposure process.

For a semiconductor device of the present invention, a prescribed pattern is formed on a semiconductor substrate in an exposure process. Furthermore, the prescribed pattern includes: a first pattern; a second pattern different in position in a height direction at which being formed from but of the same shape and size as the first pattern; and a third pattern different in position in the height direction at which being formed and in size from, but of the same shape as the first pattern.

Moreover, sizes of the first pattern and the second pattern are set at such respective magnitudes that each receive no influence of a shift in focal position given in the exposure process and size of the third pattern is set at such a magnitude that receives an influence of a shift in focal position given in the exposure process.

A semiconductor device according to a construction as described above, patterns can be formed on a semiconductor substrate in a process of a fabrication method under exposure conditions with high control accuracy by fabricating the semiconductor device using the above fabrication method for the semiconductor device; therefore, improvement can be achieved on size accuracy in patterns formed on the semiconductor substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view for describing a prescribed pattern used in a fabrication method for a semiconductor device of an embodiment;

FIG. 2 is a view showing a sectional diagram taken on line P-P of FIG. 1;

FIG. 3 is a graph showing a relationship between a size of a pattern and a defocus curve;

FIG. 4 is a graph for describing how to use a defocus curve in a fabrication method for a semiconductor device of the embodiment;

FIG. 5 is a graph for describing a relationship between a size of a formed pattern and an exposure dose;

FIG. 6 is a flow chart for describing an overall flow of a fabrication method for a semiconductor device of the embodiment;

FIG. 7 is a flow chart for describing steps for estimating a change amount of an exposure dose, a change amount of a focal position and a direction of change in focal position of a fabrication method for a semiconductor device of the embodiment;

FIG. 8 is a view for describing in what state a prescribed pattern is formed on a semiconductor substrate in a fabrication method for a semiconductor device of the embodiment;

FIG. 9 is an illustration for describing feedback schemes in a field of resistration accuracy measurement and a field exposure accuracy measurement in a prior art practice; and

FIG. 10 is a graph corresponding to Table 2.

### DESCRIPTION OF THE PREFERRED EMBODIMENT

Description will be given of a fabrication method for a semiconductor device and a semiconductor device fabricated using the method of an embodiment of the present invention based on the accompanying drawings.

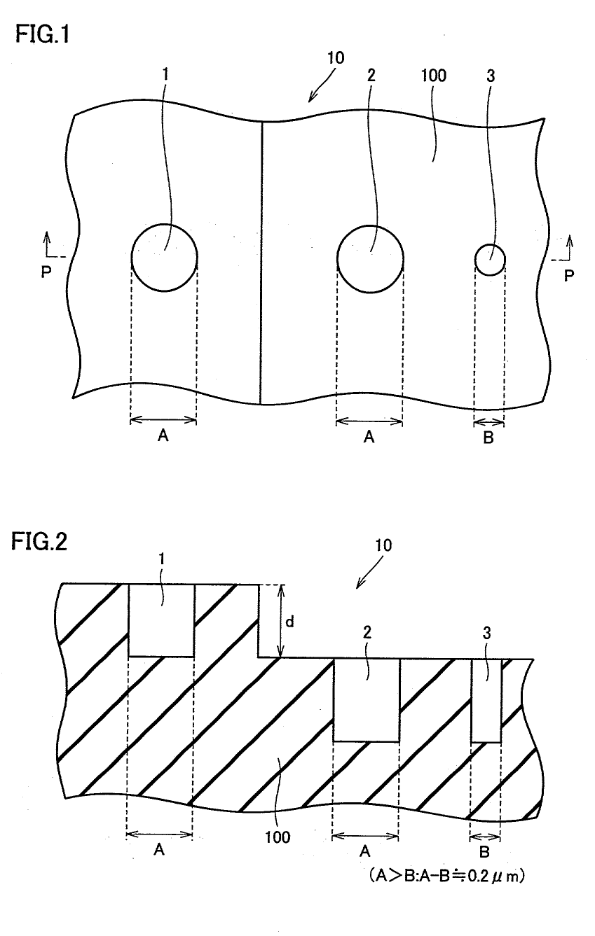

A fabrication method for a semiconductor device of the embodiment can realize control on exposure conditions by forming a prescribed pattern 10 on a semiconductor substrate in an exposure process (resist process) as shown in FIGS. 1 and 2. Therefore, prescribed pattern 10 as shown in FIGS. 1 and 2 remains in a semiconductor device fabricated by this fabrication method.

Prescribed pattern 10 includes: a pattern 1, a pattern 2 and a pattern 3, each constituted of a hole pattern. Pattern 1 and pattern 2 are different in position in a height direction from each other at which being formed but of the same shape and size as each other. On the other hand, pattern 1 and pattern 3 are different in position in a height direction at which being formed and also in size from each other but of the same shape as each other.

Note that prescribed pattern 10 of the embodiment is constructed such that when diameters of pattern 1 and pattern 2 are A and a diameter of pattern 3 is B, A>B and A−B=+0.2 μm. Furthermore, a surface height of a layer in which pattern 1 is provided is higher than that of pattern 2 and pattern 3 by a distance d.

In addition, sizes of pattern 1 and pattern 2 are set at such respective magnitudes that each receive no influence of a shift in focal position in an exposure process. Contrary to this, a size of pattern 3 is set at such a magnitude that receives an influence of a shift in focal position in the exposure process. In the embodiment, as an example, the sizes are such that the sizes of pattern 1 and pattern 2 are 0.5 μm in diameter and the size of pattern 3 is 0.3 μm in diameter.

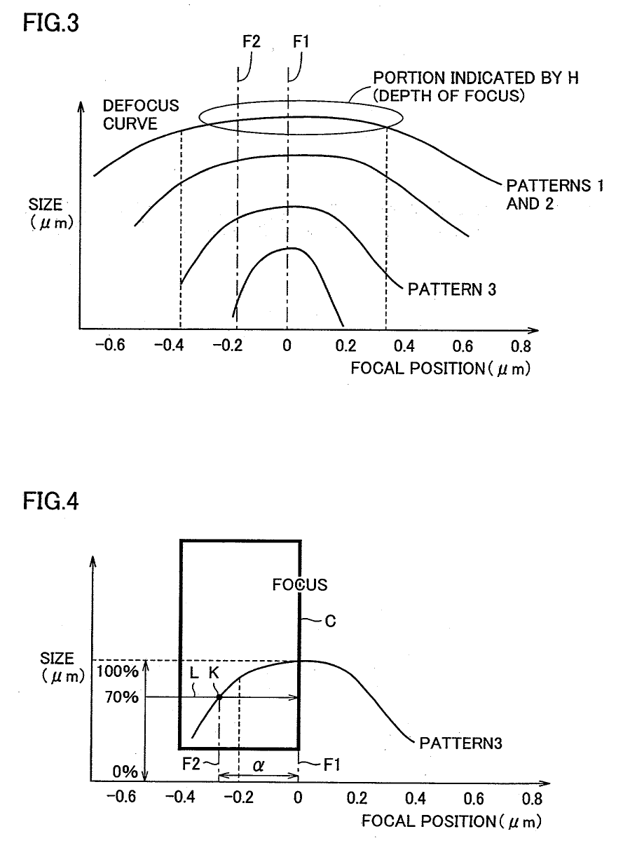

Moreover, for example, as pattern 1 and pattern 2, a pattern of a size on the uppermost defocus curve of FIG. 3 and having a relative large depth of focus is selected and as pattern 3, a pattern of a size on the second lowest defocus curve of FIG. 3, and having a relatively small depth of focus is selected.

Note that in FIG. 3, an axis indicating a focal position at which a size of formed pattern 1 when being formed is maximized is shown as a best focus axis F1 and a scale on the abscissa shows a shift in focal position to the plus side or the minus side with respect to the best focus axis of pattern 1 as a center.

An axis indicating a reference of a focal point each of pattern 2 and pattern 3 located at a position lower than pattern 1 by a distance d=0.2 μm is a reference axis F2. With a known distance of a shift in focal point in an exposure process, a size of pattern 1 can be read as a size on the graph at a point on the abscissa spaced a shift in focal point from best focus axis F1 as a reference, and a size each of pattern 2 and pattern 3 can be read on the graph at a point on the abscissa spaced a shift in focal point from best focus axis F2 as a reference.

Comparison between such 2 kinds of defocus curves with different depths of focus gives the following understanding.

Almost no change in difference (0 μm) in size arises between pattern 1 and pattern 2, both of which are formed so as to have a difference in level amounting to a distance d=0.2 μm, within plus or minus 0.4 in shift in focal position from best focus axis F1, that is in a focus depth range of 0.8. Therefore, in a case where a difference (0 μm ) in size between pattern 1 and pattern 2 changes without receiving an influence of a shift in focal position, it is concluded that a change occurs in difference (0 μm) in size between pattern 1 and pattern 2 by receiving an influence of an exposure dose only.

To the contrary, a large change in difference (A−B=+0.2 μm) in size arises between pattern 1 and pattern 3 due to a shift in focal position, both of which are formed so as to have a difference in level amounting to a distance d=0.2 μm within plus or minus 0.4 in shift in focal position from best focus axis F1, that is in a focus depth range of 0.8. Therefore, in a case where a difference (0.2 μm) in size between pattern 1 and pattern 3 changes, the change is considered to occur in two ways: one that a change in difference (0.2 μm) in size occurs between pattern 1 and pattern 3 by receiving an influence of a shift in focal position only; and the other that a change in difference (0.2 μm) in size occurs between pattern 1 and pattern 3 by receiving both of influences of a shift in focal position and a change in exposure dose.

In such a way, in a fabrication method for a semiconductor device of the present invention, sizes of pattern 1 and pattern 2, both being formed, and a distance d of a level difference between pattern 1 and pattern 2 are such that a plateau (depth of focus) of a defocus curve can be used, and a size of pattern 3 and a distance of a level difference d between pattern 1 and pattern 3 are such that a curved portion (slant portion) of a defocus curve can be used (while in a case of the embodiment, a distance of a level difference between pattern 1 and pattern 2, and a distance of a level difference between pattern 1 and pattern 3 are the same as each other, the distances of level difference may be different).

With such use of defocus curves, a comparison is enabled between a pattern hard to receive an influence of a shift in focal position and a pattern receiving a great influence of a shift in focal position. Actually, since a distance d of a level difference is determined by a film thickness of layer formed in a fabrication process, defocus curves are determined by only sizes of pattern 1, pattern 2 and pattern 3, respectively.

Note that while in general, as a size of a pattern is larger, a length of a flat portion indicated by H of FIG. 3 increases, that is a depth of focus increases, in the embodiment a size of pattern 3 of a hole shape prepared in advance is selected such that the distance d of a level difference is equal to a distance a (a distance between a vertical line from an intersection K, which is an intersection between a horizontal line L at a size of 70% of that of the best focus as 100% and a defocus line, and the best focus axis F1 on the graph).

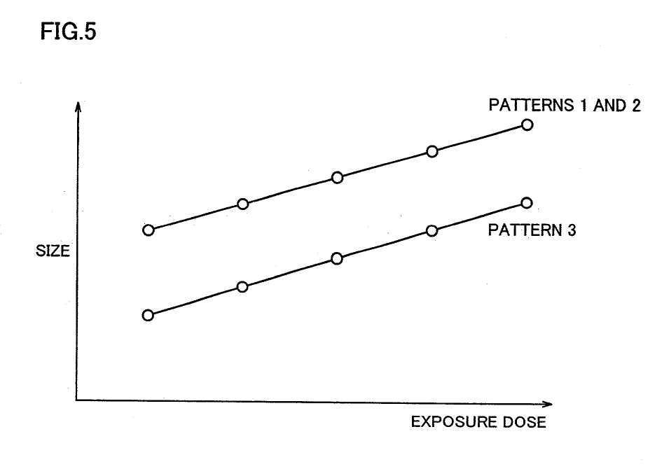

Note that while a change amount of a focal position and a direction of change in focal position are calculated using a C portion of a defocus curve on the graph shown in FIG. 4, it will be detailed later.

In the defocus curve of FIG. 4 corresponding only to the defocus curve of the pattern 3 of FIG. 3 extracted therefrom, when a focal position moves to the plus side from the intersection K, a size of formed pattern 3 when being formed increases, while when a focal position moves to the minus side, a size of formed pattern 3 when being formed decreases. Therefore, determination is enabled on whether a direction of change in focal position is to the plus side or to the minus side together with a change amount of a focal position using the defocus curve of FIG. 4.

Note that in a fabrication method of a semiconductor device of the embodiment, as for pattern 1 and pattern 2, a size of each of them is determined such that a defocus curve has a depth of focus of the order 2.5 times that of a defocus curve used for determining a size of pattern 3.

Furthermore, while in a fabrication method for a semiconductor device of the embodiment, prescribed pattern 10 as shown in FIGS. 1 and 2 is used, a prescribed pattern in use may be instead such that pattern 1 and pattern 2 are arranged in a plan in the state as shown in FIG. 1 and pattern 3 and pattern 1 assume the same position in the height direction as each other. In this case, reference axis F2 is located to the plus side with respect to best focus axis F1 in FIGS. 3 and 4, wherein in an actual exposure operation of a fabrication process for a semiconductor device, a size of pattern 3 decreases as a focal position shifts to the plus side, while as a focal point shift to the minus side, the size increases.

In addition, while in FIGS. 1 and 2, the hole patterns each having a circular shape in a plan are shown as pattern 1, pattern 2 and pattern 3, a shape of each of pattern 1, pattern 2 and pattern 3 may be a hole pattern having a square shape or a rectangular shape. Alternatively, a hole pattern having a line pattern can be a substitute therefor. Moreover, a hole pattern may be a recess or a projection.

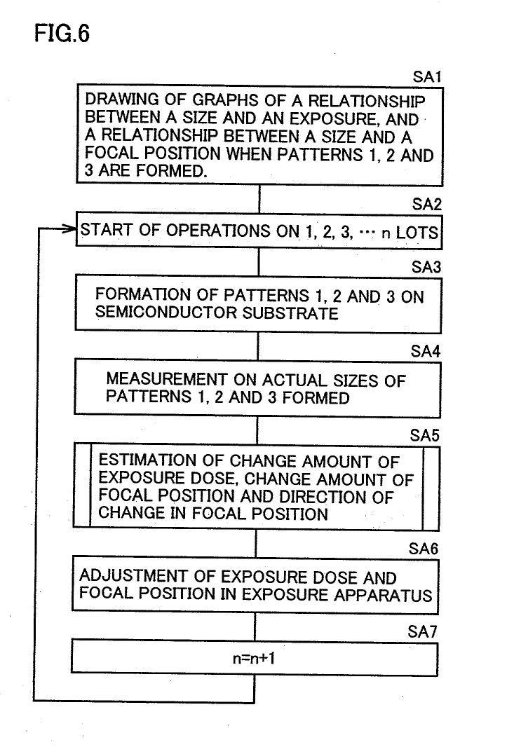

In a fabrication method for a semiconductor device of the embodiment, the following steps are performed as shown in a flow chart of FIG. 6.

A table or a graph is prepared that shows a relationship between a size of formed pattern 2 and an exposure dose when pattern 2 is formed as shown in FIG. 5 or Table 1 in various exposure conditions including changes in exposure dose and focal position in an exposure process (SA1). In addition, a graph is prepared that shows a relationship between a size of formed pattern 3 and a focal position when pattern 3 is formed (SA1).

TABLE 1

| | | A change amount of an exposure dose is | |
|---|---|---|---|
| Exp. | Size | estimated (linear interpolation) | |
| 33.5 | 0.230 | | |
| 37.5 | 0.257 | | |
| 41.5 | 0.276 | | |
| 45.5 | 0.300 | → | 0.004(slant) |
| 49.5 | 0.300 | | |
| 53.5 | 0.318 | | |
| 57.5 | 0.325 | | |
| 61.5 | 0.342 | | |

TABLE 2

| Focus | CC |
|---|---|
| −0.6 | 0.219 |
| −0.4 | 0.277 |
| −0.2 | 0.289 |
| 0.0 | 0.295 |
| 0.2 | 0.292 |
| 0.4 | 0.284 |
| 0.6 | 0.207 |

Thereafter, pattern 1, pattern 2 and pattern 3 are actually formed on a semiconductor substrate 1 using a mask having the openings for forming the patterns in an exposure process (SA3). Then, measurement is performed on actual sizes of pattern 1, pattern 2 and pattern 3, all have been thus formed (SA4).

An estimation operation is performed on an change amount of an exposure dose, a change amount of a focal position and a direction of change in focal position between a process preparing data for use in constructing FIGS. 4 and 5, and Tables 1 and 2 and actual process for fabricating a semiconductor device, using the graph or Table 1 for showing a relationship between a size of pattern 2 and an exposure dose shown in FIG. 5, the graph or representation 1-2 for showing a relationship between a size of pattern 3 and a focal position shown in FIG. 4, and actual sizes of pattern 1, pattern 2 and pattern 3 (SA5).

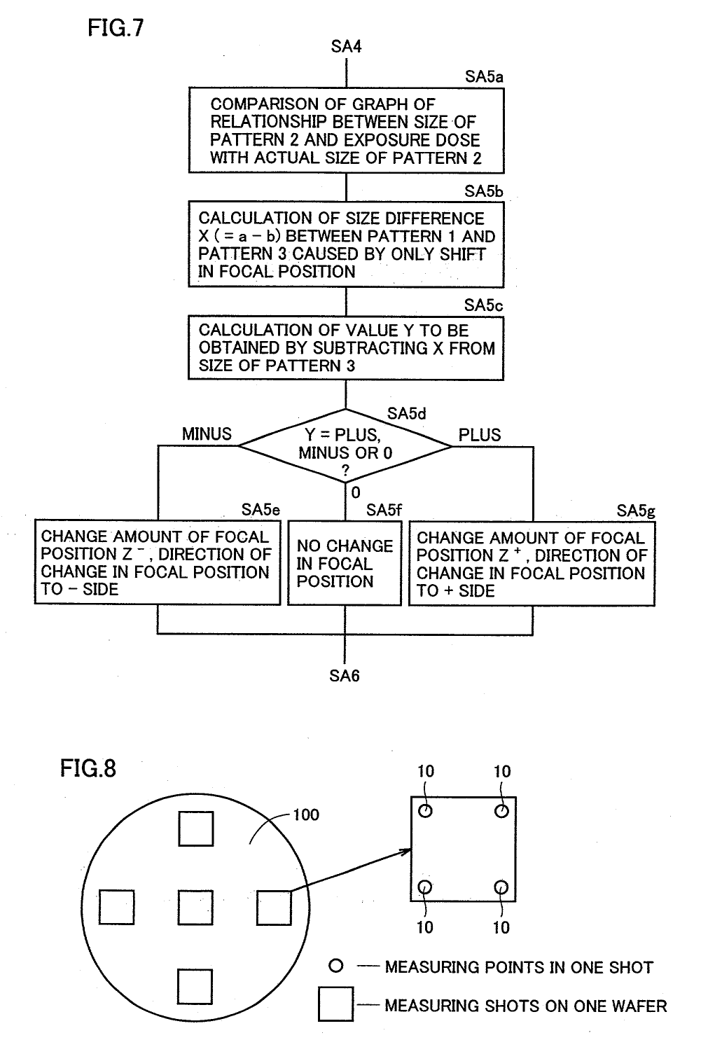

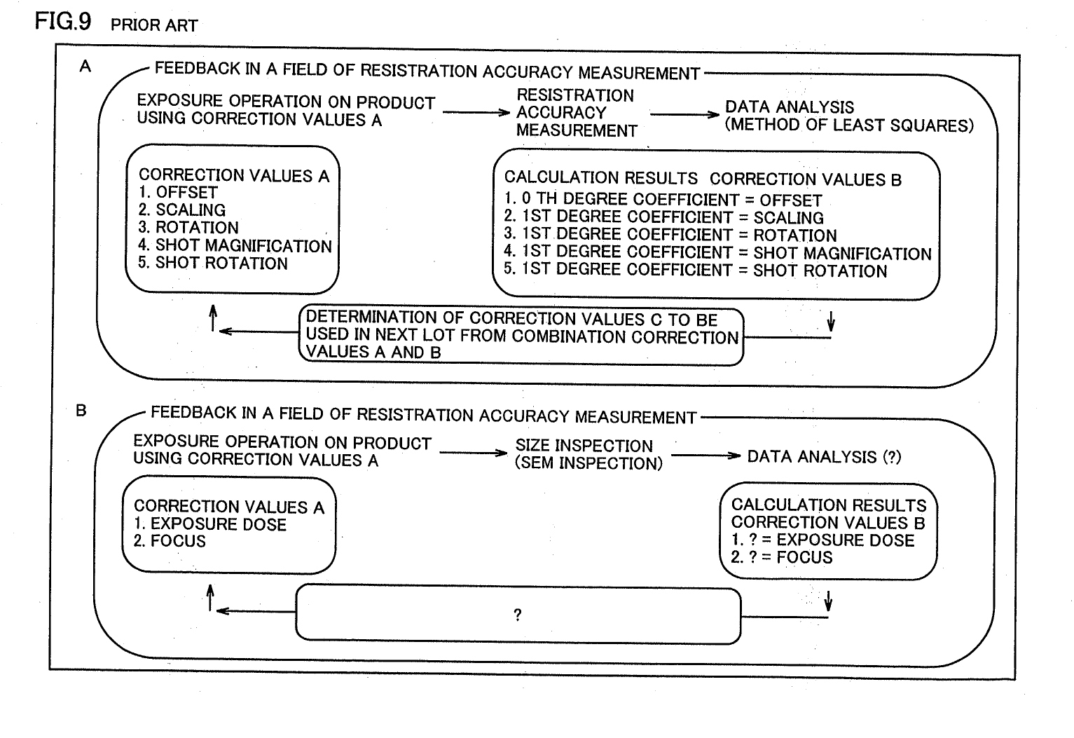

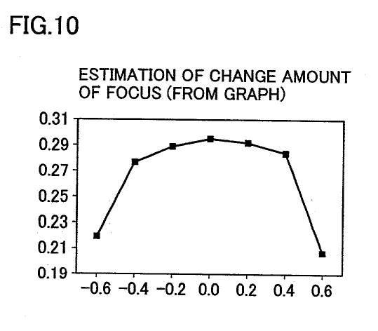

In the estimation operation (SA5), to be described in more detailed manner, the following steps are performed as shown in a flow chart of FIG. 7. First, by comparison of an actual size of pattern 2 with the graph shown in FIG. 5 of a relationship between a size of formed pattern 2 and an exposure dose when pattern 2 is formed, a change amount of an exposure amount is determined (SA5a).

The reason why the change amount of an exposure dose is obtained by comparison of the relationship with a size of the pattern 2 only is that a size of pattern 2 is set to a size receiving almost no influence of a shift in focal position as described above using FIGS. 1 to 4 and that a relationship between a size and an exposure dose between is uniquely determined by a size of pattern 2 to be formed as shown in FIG. 5. Therefore, an exposure dose to obtain a size of pattern 2 to be formed can be attained from the graph of FIG. 5 and Table 1 showing a relationship between a size of formed pattern 2 and an exposure dose when pattern 2 is formed.

Then, a value is obtained by subtracting a change amount of a size caused by a actual change in exposure dose in an exposure process of a fabrication method for a semiconductor device from a difference in size between pattern 1 and pattern 3. That is, a difference in size is obtained between pattern 1 and pattern 3 caused by only shift in focal position (SA5b). In order to obtain the difference in size, a difference a between an actual size of pattern 1 and an actual size of pattern 3 is first obtained. Then, a difference b between the actual size of pattern 1 and an actual size of pattern 2 is obtained. Furthermore, a value X of the difference b subtracted from the difference a is calculated.

Thereafter, a value Y is obtained by subtracting value X of a difference in size between pattern 1 and pattern 3 caused by only a shift in focal position from the actual size of pattern 3 (SA5c). Then, determination is performed on whether value Y is located on the plus side or on the minus side with respect to or on reference axis F2 shown in FIG. 4 or representation 1-2 showing a relation ship between a size of formed pattern 3 and a focal point when pattern 3 is formed (SA5d). Note that reference axis F2 is obtained by moving best focus axis F1 by a distance d of a difference in position in the height direction, as described above.

As a result of the determination, if value Y is shifted to the minus side with respect to the reference axis F2, a focal position is moved to the minus side (SA5e). Alternatively, if the X is on reference axis F2, a focal position stays unmoved (SA5f). Still, alternatively, if the Y value is shifted to the plus side with respect to the reference axis F2, a focal position is moved to the plus side (SA5g).

The reason why a change amount of a focal point and a direction of change in focal position can be obtained from a size of pattern 3 is as follows.

A difference in size between pattern 1 and pattern 3 receives only an influence of a shift in focal position or both influences of an exposure dose and a shift in focal position as described above using FIGS. 1 to 4. Therefore, by subtracting a difference in actually measured size between pattern 1 and pattern 2 from a difference in actually measured size between pattern 1 and pattern 3, that is by subtracting a change amount of a difference in size caused by a change amount of an exposure dose between pattern 1 and pattern 3 from a difference in actually measured size between pattern 1 and pattern 3, a change amount in size is obtained between pattern 1 and pattern 3 caused by only a shift in focal position.

As a result, a size of pattern 3 is obtained in a case under the assumption that only an influence of a shift in focal point is exercised. By comparison of a size of pattern 3 in the case under the assumption that only an influence of a shift in focal point is exercised with reference axis F2, a change amount of a focal point can be obtained including even a direction of change in focal position as described above.

An exposure dose and a focal position in the next exposure process is properly adjusted, as shown in FIG. 6, using estimated values including a change amount of an exposure dose, a change amount of a focal position and a direction of change in focal point (SA7). Note that an exposure dose can be changed by adjusting an exposure time of an exposure apparatus and a focal position can be changed by moving a position of a stepper along an optical axis in exposure operation, forward or backward, including change in sign of plus or minus.

According to a fabrication method as described above, estimation can be performed on not only a change amount of an exposure dose and a change amount of a focal position in an exposure apparatus used in an exposure process for a semiconductor device, but also a direction of change in focal point, thereby enabling fabrication of a semiconductor device even with a margin smaller than in the current state of the art.

Note that by compiling a direction of change in size of a formed pattern obtained in advance as a result of measurement in a table (including numerical values of a change in size), after lots n are repeated as many times, in correspondence to combinations of trends of change in exposure dose and a focal position (focus) as shown in Table 3, a quick adjustment in an exposure apparatus can be realized using such a table.

TABLE 3

| Combinations of parameters | | | | |
|---|---|---|---|---|
| associated with situations | | | | Combinations of measurement results |
| Exposure dose | Focus | | Hole B | 4 point average size of hole A |
| no change | plus change | | no change in size | 4 point average size of hole A in increasing trend |
| no change | plus change | | no change in size | 4 point average size of hole A in increasing trend |
| plus change | plus change | | increasing trend of size | 4 point average size of hole A in more increasing trend |
| plus change | plus change | | increasing trend of size | 4 point average size of hole A in more increasing trend |
| minus change | plus change | | decreasing trend of size | 4 point average size of hole A in no change trend |
| minus change | plus change | | decreasing trend of size | 4 point average size of hole A in no change trend |
| no change | no change | | no change in size | 4 point average size of hole A in no change trend |
| no change | no change | | no change in size | 4 point average size of hole A in no change trend |
| plus change | no change | → | increasing trend of size | 4 point average size of hole A in increasing trend |
| plus change | no change | | increasing trend of size | 4 point average size of hole A in increasing trend |
| minus change | no change | | decreasing trend of size | 4 point average size of hole A in decreasing trend |
| minus change | no change | | decreasing trend of size | 4 point average size of hole A in decreasing trend |
| no change | minus change | | no change in size | 4 point average size of hole A in decreasing trend |
| no change | minus change | | no change in size | 4 point average size of hole A in decreasing trend |
| plus change | minus change | | increasing trend of size | 4 point average size of hole A in no change trend |
| plus change | minus change | | increasing trend of size | 4 point average size of hole A in no change trend |
| minus change | minus change | | decreasing trend of size | 4 point average size of hole A in more decreasing trend |
| minus change | minus change | | decreasing trend of size | 4 point average size of hole A in more decreasing trend |

Furthermore, in a fabrication method for a semiconductor device of the embodiment, pattern 1, pattern 2 and pattern 3 all adopt a circular pattern in plan.

For this reason, since a circular pattern is formed in a smaller space, as compared with a line pattern and a box pattern, the circular pattern can suppress increase in space occupied by the pattern on semiconductor substrate 1 to the smallest possible level.

Furthermore, since an influential factor on a size of a formed pattern, caused by a shape of the pattern such as an influence on a size due to an aberration associated with a lens in an exposure apparatus can be removed as compared with a line pattern and a box patter, accuracy in adjustment of an exposure dose and a focal position can be improved to a higher level.

Moreover, in a fabrication method for a semiconductor device of the embodiment, as shown in FIG. 8, 4 sets of pattern 1, pattern 2 and pattern 3 are formed so as to constitutes respective four vertices of a rectangle.

With such a construction adopted, a change amount of an exposure dose, a change amount of a focal point and a direction of change in focal position can be estimated at each of the four vertices to obtain 4 data of each of the change amount of an exposure dose, the change amount of a focal position and the direction of change in focal position, respectively and by attaining average values of the 4 data of each, more of improvement is achieved on accuracy in adjustment of an exposure dose and a focal position.

Furthermore, a position in the height direction of each of patterns constituting each of 4 vertices can be calculated from 4 data sets of the exposure dose and the focal position of at least one of pattern 1, pattern 2 and pattern 3. As a result, a flatness of a surface of a layer in which there are formed patterns at 4 vertices constituting a rectangle or of a surface of an underlying layer of a layer in which the patterns can be measured without providing a new pattern additionally.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A fabrication method for a semiconductor device, capable of controlling exposure conditions by forming a prescribed pattern on a semiconductor substrate in an exposure process,
wherein said prescribed pattern includes: a first pattern;
a second pattern different in position in a height direction at which being formed from, but of the same shape and size as said first pattern; and
a third pattern different in position in said height direction at which being formed and in size from, but of the same shape as said first pattern,
sizes of said first pattern and said second pattern being set at such respective magnitudes that each receive no influence of a shift in focal position given in said exposure process and
size of said third pattern being set at such a magnitude that receives an influence of a shift in focal position given in said exposure process, comprising:
a data preparation step for preparations of obtaining data showing a relationship between a size and an exposure dose when said second pattern is formed and data showing a relationship between a size and a focal position when said third pattern is formed in various exposure conditions including changes in exposure dose and focal position in said exposure process;
a pattern formation step of forming said first pattern, said second pattern and said third pattern in said exposure process in actual fabrication for a semiconductor device;
an actual size measurement step of measuring an actual size of each of said first pattern, said second pattern and said third pattern, formed in said pattern formation step;
an estimation step of estimating a change amount of said exposure dose, a change amount of said focal position and a direction of change in focal position between said data preparation step and said actual size measurement step using said data showing a relationship between a size and an exposure dose when said second pattern is formed and said data showing a relationship between a size and a focal position when said third pattern is formed, and said actual sizes of said first pattern, said second pattern and said third pattern; and
an exposure-dose focal-position adjustment step of properly adjusting an exposure dose and a focal position in a next exposure step using said change amount of said exposure dose, said change amount of said focal position and said direction of change in focal position estimated in said estimation step,
wherein said estimation step includes:
an exposure-dose change-amount determination step of determining said change amount of said exposure dose by comparing said actual size of said second pattern with said data showing a relationship between a size and an exposure dose when said second pattern is formed;
a size difference calculation step of calculating a value to be obtained by subtracting a difference between said actual size of said first pattern and said actual size of said second pattern, from a difference between said actual size of said first pattern and said actual size of said third pattern as a difference in size between said first pattern and said third pattern caused only by said shift in focal position; and
a focal-position-change-amount focal-position-change-direction determination step of estimating said change amount of said focal position and said direction of change in focal position by determining whether or not a size difference between said first pattern and said third pattern caused only by a shift in focal point subtracted from said actual size of said third pattern is on the positive side or the negative side with respect to, or on a reference axis spaced said distance of a difference in position in a height direction from a best focus axis of said data showing a relationship between a size and a focal position when said third pattern is formed.

2. The fabrication method for a semiconductor device according to claim 1, wherein said first pattern, said second pattern and said third pattern are circular in a plan view.

3. The fabrication method for a semiconductor device according to claim 1, wherein at least three said prescribed patterns are provided, and said first patterns, said second patterns or said third patterns formed in one layer are not positioned on one straight line when viewed two-dimensionally.

4. A semiconductor device with a prescribed pattern formed on a semiconductor substrate in an exposure process, in which said prescribed pattern comprises: a first pattern;
a second pattern different in position in a height direction at which being formed from but of the same shape and size as said first pattern; and
a third pattern different in position in said height direction at which being formed and in size from, but of the same shape as said first pattern,
sizes of said first pattern and said second pattern being set at such respective magnitudes that each receive no influence of a shift in focal position given in said exposure process and
size of said third pattern being set at such a magnitude that receives an influence of a shift in focal position given in said exposure process.

5. The semiconductor device according to claim 4, wherein said first pattern, said second pattern and said third pattern are circular in a plan view.

6. The semiconductor device according to claim 4, where in at least three said prescribed patterns are provided, and said first patterns, said second patterns or said third patterns formed in one layer are not positioned on one straight line when viewed two-dimensionally.
